(19) United States
(12) Patent Application Publication
(10) Pub. No.: US 2024/0234134 A1
(43) Pub. Date: Jul. 11, 2024

(54) METHOD FOR PRODUCING A GROWTH SUBSTRATE AND GROWTH SUBSTRATE

(71) Applicant: ams-OSRAM International GmbH, Regenburg (DE)

(72) Inventors: Viola Miran Kueller, Barbing (DE); Adrian Stefan Avramescu, Regensburg (DE); Hans-Jürgen Lugauer, Sinzing (DE); Marc Hoffman, Regensburg (DE); Andreas Waag, Würzburg (DE); Lukas Peters, Braunschweig (DE); Christoph Margenfeld, Braunschweig (DE)

(21) Appl. No.: 18/291,196

(22) PCT Filed: Jul. 7, 2022
(86) PCT No.: PCT/EP2022/068915

§ 371 Date: Jan. 22, 2024

(30) Foreign Application Priority Data
Jul. 29, 2021 (DE) 10 2021 119 713.9

(51) Int. Cl. H01L 21/02

(52) U.S. Cl. CPC H01L 21/02389; H01L 21/02664

(57) ABSTRACT

In an embodiment a method for producing a growth substrate includes providing a substrate with a main surface, arranging a layer sequence on the main surface of the substrate, wherein the layer sequence comprises at least one semiconductor layer comprising a III-V compound semiconductor material, and annealing the layer sequence on the substrate, wherein the layer sequence comprises at least one intermediate layer and/or wherein a cover layer is arranged on the layer sequence, wherein a temperature during annealing is at least 1400° C., wherein the intermediate layer comprises a material selected from the following group: carbides, nitrides, oxides, oxynitrides, wherein the nitrides are nitrides of silicon, titanium, tantalum, yttrium, hafnium, scandium, tungsten, or zirconium, and wherein the cover layer comprises one of the following materials: tungsten nitride, aluminum carbonitride, molybdenum, tungsten, titanium, tantalum, hafnium, aluminum, titanium tungsten, graphite, or a photoresist.

### CROSS-REFERENCE TO RELATED APPLICATIONS

This patent application is a national phase filing under section 371 of PCT/EP2022/068915, filed Jul. 7, 2022, which claims the priority of German patent application 102021119713.9, filed Jul. 29, 2021, each of which is incorporated herein by reference in its entirety.

### TECHNICAL FIELD

A method for producing a growth substrate and a growth substrate are specified.

### SUMMARY

Embodiments provide a method for producing a growth substrate with improved material properties. Further embodiments provide a growth substrate that exhibits improved material properties.

A method for producing a growth substrate is disclosed. For example, the growth substrate is a growth substrate for an epitaxial semiconductor layer sequence which is configured to generate or detect electromagnetic radiation.

According to an embodiment of the method, a substrate is provided. The substrate comprises thereby a main surface. Furthermore, the substrate may also comprise or consist of one of the following materials: (In,Al,Ga)N, silicon carbide, sapphire.

According to an embodiment of the method, a layer sequence is arranged on the main surface of the substrate. In particular, the layer sequence is in direct contact with the substrate. The layer sequence comprises at least one semiconductor layer comprising a III-V compound semiconductor material. Preferably, the semiconductor layer consists of the III-V compound semiconductor material. For example, the layer sequence is formed from one semiconductor layer.

A III-V compound semiconductor material comprises at least one element from the third main group, such as B, Al, Ga, In, and one element from the fifth main group, such as N, P, As. In particular, the term “III-V compound semiconductor material” comprises the group of binary, ternary or quaternary compounds which contain at least one element from the third main group and at least one element from the fifth main group, such as nitride, phosphide and arsenide compound semiconductor materials. Such a binary, ternary or quaternary compound may also comprise, for example, one or more dopants and additional components.

According to an embodiment of the method, the layer sequence comprises at least one intermediate layer. In particular, the intermediate layer comprises a crystal structure with a similar unit cell as a crystal structure of the semiconductor layer. As alternative or in addition to the intermediate layer in the layer sequence, a cover layer may be arranged on the layer sequence. In particular, the cover layer is arranged directly on the layer sequence. In other words, the cover layer and the layer sequence can be in direct contact. Furthermore, the cover layer can, for example, completely cover the layer sequence.

According to an embodiment of the method, the layer sequence is annealed on the substrate. In particular, the annealing is carried out in an atmosphere comprising N₂, Ar, NH₃ or CO or a combination of two or more of these gases or formed from these gases or a combination of two or more of these gases. Thereby, up to 100 ppm O₂ may be present in the atmosphere. For example, the layer sequence is annealed on the substrate for a time between 1 hour and 12 hours, inclusive, preferably between 1 hour and 6 hours, inclusive, particularly preferably between 1 hour and 5 hours, inclusive.

Annealing is used in particular to improve the material properties of the growth substrate, for example by reducing the number of defects and/or surface roughness. A defect can be, for example, a foreign atom, a vacancy, a defect, a stacking fault, or a dislocation in the growth substrate.

For example, the layer sequence comprises grain boundaries. In particular, the grain boundaries are also considered defects in the growth substrate. For example, the grain boundaries do not run parallel to the main surface of the substrate. It is also possible that the grain boundaries run through two directly adjacent layers of the layer sequence. For example, a grain boundary runs through a semiconductor layer and an intermediate layer. Regions adjacent to a grain boundary preferably comprise the same crystal structure with a unit cell, but the unit cells of the regions are at least slightly differently oriented.

In particular, at least a part of the semiconductor layer is recrystallized during annealing, whereby the number of defects in the layer sequence is at least reduced. In particular, the intermediate layer and/or the cover layer do not hinder the recrystallization of the semiconductor layer, whereby an effectiveness of the annealing is maintained.

According to a preferred embodiment of the method, a substrate having a main surface is provided, a layer sequence is arranged on the main surface of the substrate and the layer sequence is annealed on the substrate. The layer sequence comprises at least one semiconductor layer comprising a III-V compound semiconductor material. The layer sequence further comprises at least one intermediate layer and/or a cover layer is arranged on the layer sequence.

Preferably, the steps of the method are carried out in the order indicated.

Conventionally produced growth substrates usually comprise a substrate and a single semiconductor layer, such as an AlN semiconductor layer. During annealing, the conventionally produced growth substrates are arranged in such a way that the semiconductor layers of two growth substrates lie directly on top of each other. In other words, the growth substrates are annealed “face-to-face”. However, this results in edge effects and problems when handling and separating the growth substrates. In particular, the separation can lead to contamination or damage of the growth substrates. Furthermore, temperatures and times for annealing must be selected so that no defects occur in the semiconductor layer and on the surface of the semiconductor layer.

The defects can be generated, for example, by diffusion from a material of the substrate into the semiconductor layer, by thermal decomposition at the surface of the semiconductor layer and/or by incorporation of foreign atoms from the atmosphere during annealing.

With the at least one intermediate layer, it is advantageously possible to prevent diffusion of a material of the substrate into the semiconductor layer. Thus, a decomposition of the semiconductor layer and the surface of the semiconductor layer can be prevented. The at least one intermediate layer also makes it possible to reduce the thickness of the semiconductor layer. This is due to the fact that in conventionally produced growth substrates, the thickness of the semiconductor layer is selected such that a part of the semiconductor layer is used as a protective layer.

Due to the cover layer the layer sequence and thus also the semiconductor layer are protected from the atmosphere during annealing. In particular, no foreign atoms from the atmosphere can be incorporated into the semiconductor layer. This makes it possible to make the method independent of the atmosphere during annealing. In addition, a desorption of material from the layer sequence is prevented. Furthermore, a “face-to-face” annealing of the growth substrates can be avoided by the cover layer, which prevents the problems associated with handling and separating of the growth substrates. In this way, both producibility and yield are improved compared to conventionally produced growth substrates.

The intermediate layer and the cover layer therefore generally have the advantage of improving a process stability of the method. In addition, a higher temperature can be made possible during annealing, which can additionally improve the material properties of the growth substrate. In particular, a time for annealing can also advantageously be extended or shortened.

According to an embodiment of the method, the III-V compound semiconductor material is a nitride compound semiconductor material. Nitride compound semiconductor materials are III-V compound semiconductor materials that contain nitrogen, such as the materials from the system InₓAl_{y}Ga_{1-x-y}N with 0≤x≤1, 0≤y≤1 and x+y≤1. Preferably, the III-V compound semiconductor material is AlN, Al_{y}Ga_{1-y}N, or GaN. For example, the III-V compound semiconductor material is AlN.

According to an embodiment of the method, the layer sequence comprises a plurality of semiconductor layers and a plurality of intermediate layers or is formed from a plurality of semiconductor layers and a plurality of intermediate layers. In this embodiment, the semiconductor layers and the intermediate layers are arranged alternately, for example in direct contact with each other. Due to an alternating arrangement of the semiconductor layers and the intermediate layers the material properties of the semiconductor layers are effectively improved.

According to an embodiment of the method, the semiconductor layer and/or the intermediate layer are deposited by metal organic vapor-phase epitaxy (MOVPE), sputtering, plasma-enhanced chemical vapor deposition (PECVD) or atomic layer deposition (ALD). In particular, the semiconductor layer is deposited by sputtering.

In particular, it is also possible for an intermediate layer to be generated by modifying a semiconductor layer. For example, a semiconductor layer can be modified by doping or changing the stoichiometry. For example, the semiconductor layer is doped with foreign atoms by ion implantation.

According to at least one embodiment of the method, a temperature during annealing is at least 1400° C.

According to an embodiment of the method, a temperature during annealing is at least 1500° C. In particular, the temperature is at least 1600° C., preferably at least 1700° C. Preferably, the temperature is at most 2200° C., particularly preferably at most 2000° C. For example, the temperature during annealing is 1700° C.

According to an embodiment of the method, the cover layer is applied to the layer sequence before the growth substrate is annealed. In particular, the cover layer is applied by one of the following methods: MOVPE, sputtering, PECVD, ALD, spray coating, spin coating. During the application of the cover layer and/or annealing, it is possible that a material of the cover layer migrates. In particular, the material of the cover layer accumulates at the grain boundaries of the layer sequence, which at least hinders the continuation of the grain boundaries.

In particular, the cover layer is easy to remove. This means that the cover layer can be effectively removed by suitable methods, such as etching methods or chemical-mechanical polishing, without affecting the underlying layer sequence.

For example, the cover layer comprises a thickness of between 100 nanometers and 1000 nanometers.

According to an embodiment of the method, the cover layer comprises at least one of the following materials or is formed from one of the following materials: tungsten nitride (WN), aluminum carbonitride (AlCN), silicon nitride (Si₃N₄), molybdenum (Mo), tungsten (W), titanium (Ti), tantalum (Ta), hafnium (Hf), aluminum (Al), titanium tungsten (TiW), graphite, photoresists.

In particular, tungsten nitride is characterized by a high melting temperature and good water solubility. Silicon nitride can be removed using fluoride reagents such as hydrofluoric acid or buffered hydrofluoric acid (buffered oxide etch, BOE). Molybdenum is characterized in particular by a good stability at high temperatures and can be removed using wet chemical methods, for example. In the case of graphite, it is in particular possible to remove it by annealing or in-situ during epitaxial deposition of an epitaxial semiconductor layer sequence in a growth reactor.

In particular, the material of the cover layer can react with the semiconductor layer and form alloys, for example. The cover layer is preferably more stable than the semiconductor layer.

“Stable” means here and in the following that a layer or material shows no or only minor changes in structure and/or chemical composition under thermal, chemical and/or mechanical stress. In other words, the structure and/or chemical composition is not changed under the stress.

According to an embodiment of the method, the cover layer is removed again after annealing. For example, dry etching, wet chemical etching, chemical-mechanical polishing (CMP) or in-situ etching can be used during the epitaxial deposition of an epitaxial semiconductor layer sequence.

A growth substrate is further specified. Preferably, the growth substrate is producible by the method for producing a growth substrate described herein. Features and embodiments described in combination with the method therefore also apply to the growth substrate and vice versa.

According to an embodiment, the growth substrate comprises a substrate comprising a main surface and a layer sequence arranged on the main surface of the substrate. The layer sequence comprises at least one semiconductor layer comprising a III-V compound semiconductor material. Furthermore, the layer sequence may comprise at least one intermediate layer. Alternatively or additionally, it is possible that a cover layer is arranged on the layer sequence. In particular, the layer sequence consists of one semiconductor layer.

According to an embodiment of the growth substrate, the layer sequence comprises at least one intermediate layer. The layer sequence then comprises at least one semiconductor layer and at least one intermediate layer.

According to an embodiment of the growth substrate, the layer sequence comprises a plurality of semiconductor layers and a plurality of intermediate layers, wherein the semiconductor layers and the intermediate layers are arranged alternately. Preferably, the layer sequence comprises a maximum of five, particularly preferably a maximum of three semiconductor layers. Preferably, the layer sequence comprises a maximum of five, particularly preferably a maximum of two intermediate layers. In particular, a number of semiconductor layers is independent of a number of intermediate layers. This means, for example, that the layer sequence comprises exactly three semiconductor layers and exactly two intermediate layers. However, the layer sequence can also comprise, for example, exactly two semiconductor layers and exactly two intermediate layers.

According to an embodiment of the growth substrate, one of the semiconductor layers or the one semiconductor layer is directly adjacent to the substrate. In other words, a semiconductor layer is arranged directly on the substrate without another layer being arranged between the semiconductor layer and the substrate. The semiconductor layer is therefore in direct contact with the substrate.

According to an embodiment of the growth substrate, one of the intermediate layers or the intermediate layer of the layer stack is directly adjacent to the substrate. In particular, the intermediate layer that is directly adjacent to the substrate comprises no grain boundaries. In other words, the intermediate layer that is directly adjacent to the substrate is free of grain boundaries.

In this preferred embodiment, at least the intermediate layer, which is directly adjacent to the substrate, prevents or reduces diffusion of material from the substrate into a semiconductor layer. This prevents or at least reduces degradation of the semiconductor layer, thereby improving the material properties of the growth substrate compared to conventional growth substrates.

According to an embodiment of the growth substrate, the semiconductor layer comprises a thickness of at most 600 nanometers, preferably at most 400 nanometers. In the case that the layer sequence comprises more than one semiconductor layer, it is possible that all semiconductor layers of the layer sequence comprise the same thickness. Alternatively, at least two semiconductor layers of the layer sequence comprising a plurality of semiconductor layers may comprise different thicknesses.

In particular, the layer sequence comprises a thickness of no more than 600 nanometers, preferably no more than 400 nanometers.

According to an embodiment of the growth substrate, the intermediate layer comprises between one and 100 monolayers, both inclusive. Preferably, the intermediate layer comprises between one and 50 monolayers, both inclusive, particularly preferably between one and 20 monolayers, both inclusive, in particular between one and three monolayers, both inclusive. Advantageously, a thickness of the intermediate layer is selected such that the crystal structure of the semiconductor layer is not or only slightly influenced.

According to an embodiment of the growth substrate, the intermediate layer comprises a material selected from the group consisting of carbides, nitrides, oxides and oxynitrides. Preferably, the intermediate layer is formed from a carbide, nitride, oxide or oxynitride. In particular, the nitrides are nitrides of silicon, titanium, tantalum, yttrium, hafnium, scandium, tungsten, aluminum, boron and zirconium. In particular, the carbides are carbides of silicon, titanium, tantalum, yttrium, hafnium, tungsten and aluminum. In particular, the oxides are oxides of beryllium, magnesium or aluminum. For example, silicon nitride, silicon carbide and aluminum oxynitride are suitable materials for the intermediate layer.

Furthermore, the material of the intermediate layer can be doped with a dopant. In particular, the intermediate layer comprises a nitride, which is doped, for example, with magnesium, silicon and/or beryllium as a dopant. For example, the material of the intermediate layer is a doped aluminum nitride, in particular AlN:Mg, AlN:Si and AlN:Be.

In particular, the material of the intermediate layer can form an alloy with the III-V compound semiconductor material of the semiconductor layer.

In the case where the layer sequence comprises a plurality of intermediate layers, the intermediate layers may comprise different materials and thicknesses. In other words, the material and thickness of a first intermediate layer are selected independently of the material and thickness of a second intermediate layer. Alternatively, in the case of a plurality of intermediate layers, the intermediate layers may comprise the same material and/or the same thickness.

According to at least an embodiment of the growth substrate, the material of the intermediate layer is stable at a temperature of greater than or equal to 1400° C., in particular greater than or equal to 1500° C.

According to an embodiment, the material of the intermediate layer is stable at a temperature of greater than or equal to 1600° C., preferably at a temperature of greater than or equal to 1900° C. In particular, the material of the intermediate layer comprises a melting temperature, sublimation temperature and/or decomposition temperature of greater than or equal to 1600° C., preferably greater than or equal to 1900° C., particularly preferably greater than or equal to 2000° C. Due to the high temperature stability of the material of the intermediate layer, the intermediate layer makes it possible to improve the material properties of the growth substrate.

In particular, the material of the intermediate layer can migrate and accumulate at grain boundaries of the layer sequence. This has the advantage of preventing the grain boundaries from propagating. The intermediate layer is also suitable for compensating for minor material unevenness in a layer directly below it.

According to an embodiment of the growth substrate, the material of the intermediate layer comprises a hexagonal unit cell, which is in particular similar to the unit cell of the III-V compound semiconductor material of the semiconductor layer. This makes it possible for the crystal structure of the III-V compound semiconductor material of the semiconductor layer to be retained throughout the entire layer sequence.

According to an embodiment of the growth substrate, the material of the intermediate layer grows in the [111] direction of the cubic crystal lattice. This also has the advantage that the crystal structure of the III-V compound semiconductor material of the semiconductor layer is preserved throughout the entire layer sequence.

Further advantageous embodiments, designs and developments of the growth substrate and of the method for producing a growth substrate result from the following exemplary embodiments shown in combination with the figures.

### BRIEF DESCRIPTION OF THE DRAWINGS

FIGS. 1-7 show, by means of schematic sectional views, steps of a method for producing a growth substrate according to an exemplary embodiment; and

FIGS. 8-14 show a schematic sectional view of a growth substrate according to an exemplary embodiment in each case.

### DETAILED DESCRIPTION OF ILLUSTRATIVE EMBODIMENTS

Elements that are identical, similar or have the same effect are marked with the same reference signs in the figures. The figures and the proportions of the elements shown in the figures are not to be regarded as true to scale. Rather, individual elements, in particular layer thicknesses, may be shown in exaggerated size for better visualization and/or understanding.

In a first step of a method for producing a growth substrate 1 according to the exemplary embodiment of FIGS. 1 to 7, a substrate 2 having a main surface is provided (FIG. 1). In particular, the substrate 2 is sapphire.

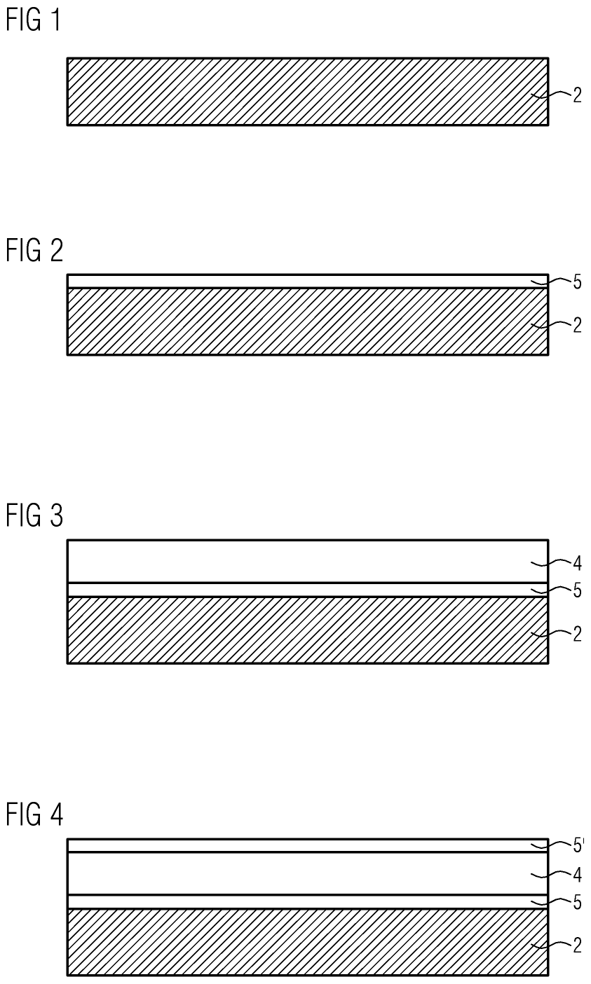

A layer sequence 3 is then arranged on the main surface of the substrate 2. For example, as shown in FIG. 2, an intermediate layer 5 is applied to the main surface of the substrate. In particular, the intermediate layer 5 comprises silicon nitride, which is applied, for example, by plasma-enhanced chemical vapor deposition (PECVD).

A semiconductor layer 4 is arranged on the intermediate layer 5 (FIG. 3). In particular, the semiconductor layer 4 is a layer that comprises or consists of aluminum nitride (AlN). The AlN is applied to the intermediate layer 5 by sputtering, for example.

A further intermediate layer 5′ is arranged on the semiconductor layer 4 (FIG. 4). In particular, the further intermediate layer 5′ is free of silicon nitride. In other words, the intermediate layers 5, 5′ are formed from different materials. It is therefore possible for the further intermediate layer 5′ to be applied by deposition processes other than PECVD.

To complete the layer sequence 3, a further semiconductor layer 4′ is applied to the further intermediate layer 5′, as shown in FIG. 5. For example, the semiconductor layer 4′ comprises or consists of AlN.

The layer sequence according to the present exemplary embodiment thus comprises exactly two semiconductor layers 4, 4′ and exactly two intermediate layers 5, 5′. The semiconductor layers 4, 4′ and the intermediate layers 5, 5′ are arranged alternately, in other words in turns, with the intermediate layer 5 being arranged directly on the substrate 2.

A cover layer 6 is applied on the layer sequence 3, as shown in FIG. 6. The cover layer 6 is arranged on a side of the layer sequence 3 facing away from the substrate 2. In particular, the cover layer 6 is applied directly to the semiconductor layer 4′. Compared with the intermediate layers 5, 5′, the cover layer 6 comprises a significantly greater thickness. For example, the cover layer 6 comprises TiW or is formed from TiW. The cover layer 6 serves to protect the semiconductor layers 4, 4′ from environmental influences.

After the cover layer 6 has been applied to the layer sequence 3, the growth substrate is annealed. In particular, annealing is carried out at a temperature of approximately 1700° C. Due to the annealing defects in the growth substrate are reduced. The intermediate layers 5 and the cover layer 6 serve to further improve the material properties of the growth substrate 1. In particular, the number of grain boundaries 7 in the layer sequence 3 is reduced during annealing. The intermediate layer 5 prevents material from the substrate 2 from diffusing into the semiconductor layers 4, 4′. The cover layer 6, on the other hand, protects the semiconductor layers 4, 4′ from the atmosphere during annealing. For example, the incorporation of oxygen atoms into the semiconductor layers 4, 4′ with AlN is prevented.

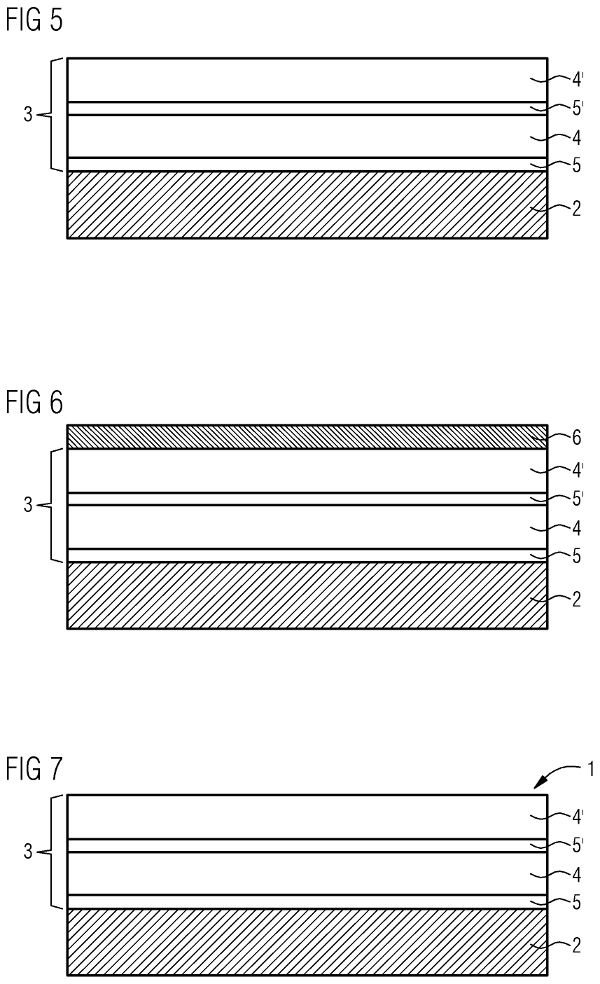

After annealing, the cover layer 6 is removed to produce the finished growth substrate 1 shown in FIG. 7. For example, the cover layer 6 is removed by a wet chemical method without corroding the underlying semiconductor layer 4′.

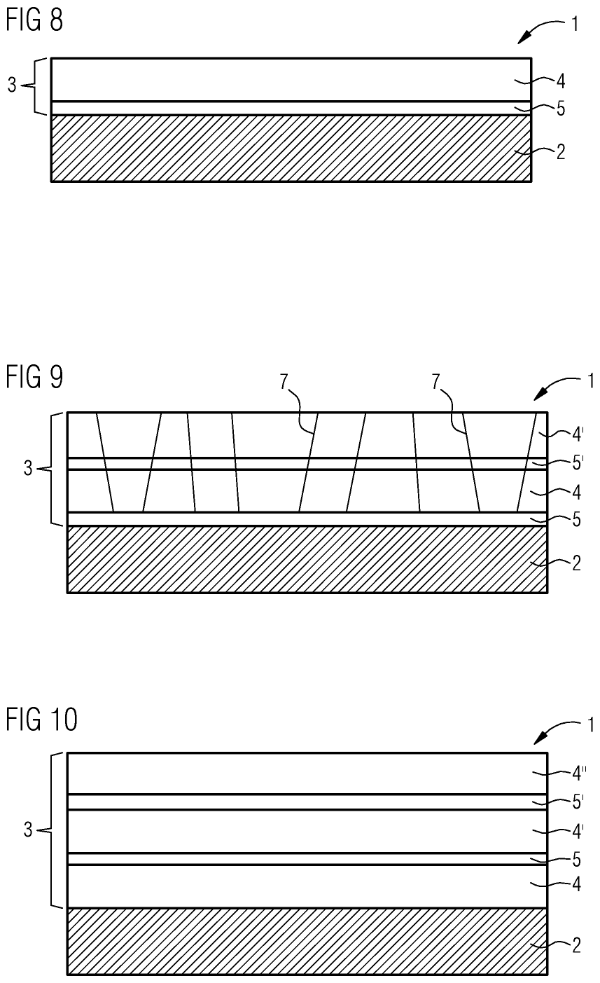

FIG. 8 shows a growth substrate 1 according to an exemplary embodiment. The growth substrate 1 comprises a substrate 2 with a main surface. In particular, the substrate 2 is sapphire. A layer sequence 3 is arranged on the main surface of the substrate 2. In the present case, the layer sequence 3 is formed from an intermediate layer 5 and a semiconductor layer 4. The semiconductor layer 4 comprises AlN or is formed from AlN. The layer sequence 3 is arranged on the main surface of the substrate 2 in such a way that the intermediate layer 5 is in direct contact with the substrate 2. The intermediate layer 5 prevents or at least reduces material from the substrate 2 getting into the semiconductor layer 4 during annealing and thus leading to defects.

In contrast to the growth substrate 1 of FIG. 8, FIG. 9 shows a growth substrate 1 with a layer sequence 3 with a plurality of intermediate layers 5, 5′ and semiconductor layers 4, 4′. In particular, the growth substrate 1 can be produced using the method described in connection with FIGS. 1 to 7.

In the growth substrate of FIG. 9, the layer sequence 3 comprises exactly two semiconductor layers 4, 4′ comprising AlN and exactly two intermediate layers 5, 5′ arranged alternately. As in the previous exemplary embodiment, the layer sequence 3 is arranged on a substrate 2, with the intermediate layer 5 being in direct contact with the substrate 2. The intermediate layers 5, 5′ comprise either the same material or different materials.

In FIG. 9 grain boundaries 7 that run through the layer sequence 3 are shown. The grain boundaries 7 begin in the semiconductor layer 4, which is arranged between the intermediate layers 5, 5′. This means that the intermediate layer 5, which is directly adjacent to the substrate 2, comprises no grain boundaries 7. The material of the intermediate layer 5′, which is arranged between the semiconductor layers 4, 4′, is selected such that the grain boundaries 7 can extend through this intermediate layer 5′. The intermediate layer 5′ serves to compensate for imbalances in the semiconductor layer 4. Preferably, a number of the grain boundaries 7 can be reduced by annealing the growth substrate 1.

FIG. 10 shows a growth substrate 1 according to a further exemplary embodiment. Presently, the growth substrate 1 comprises a substrate 2 and a layer sequence 3. In contrast to the previously described growth substrates 1, the layer sequence 3 of the present growth substrate 1 comprises an odd number of layers. The layer sequence 3 comprises exactly three semiconductor layers 4, 4′, 4″ and exactly two intermediate layers 5, 5′. The intermediate layers 5, 5′ are each arranged between two semiconductor layers 4,4′, 4″. In other words, the layer sequence 3 comprises the intermediate layers 5, 5′ and the semiconductor layers 4, 4′, 4″ in an alternating order. Thereby, the semiconductor layer 4 is directly adjacent to the substrate 2.

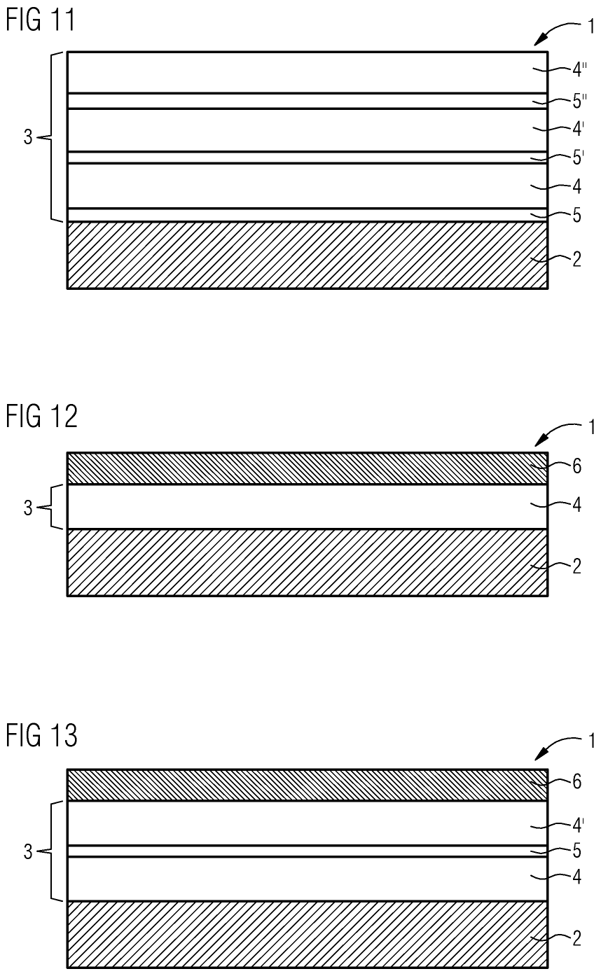

The growth substrate 1 according to the exemplary embodiment of FIG. 11 shows an even number of layers in a layer sequence 3 arranged on a main surface of a substrate 2. The layer sequence 3 comprises exactly three intermediate layers 5, 5′, 5″ and exactly three semiconductor layers 4,4′, 4″, which are arranged alternately. The layer sequence 3 is applied to the substrate 2 in such a way that the intermediate layer 5 is in direct contact with the substrate 2.

FIG. 12 shows a growth substrate 1 according to an exemplary embodiment with a substrate 2, a layer sequence 3 and a cover layer 6. Presently, the layer sequence 3 consists of exactly one semiconductor layer 4. The layer sequence 3 thus does not comprise intermediate layers 5. The semiconductor layer 4 is arranged between the cover layer 6 and the substrate 2. In particular, the cover layer 6 is only removed during an application of an epitaxial semiconductor layer sequence to the growth substrate 1. In other words, the cover layer 6 is removed in-situ. This has the advantage that the semiconductor layer 4 is not only protected from external influences during annealing, but also during possible subsequent process steps that take place before the epitaxial semiconductor layer sequence is applied.

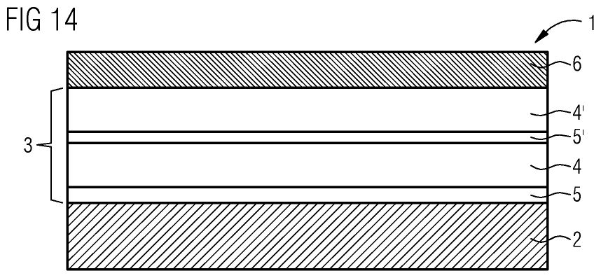

FIG. 13 shows a growth substrate 1 with a layer sequence 3 comprising an odd number of layers. The layer sequence 3 comprises exactly two semiconductor layers 4,4′, between which an intermediate layer 5 is arranged. The layer sequence 3 is further arranged on a substrate 2, which comprises in particular sapphire. The semiconductor layer 4 is directly adjacent to the substrate 2. A cover layer 6 is arranged on the layer sequence 3. The cover layer 6 is applied to the layer sequence 3 in such a way that it is arranged on a side of the layer sequence 3 that is opposite the substrate 2. In other words, the substrate 2 and the cover layer 6 are located on different sides of the layer sequence 3.

In particular, the intermediate layer 5 consists of a material that is capable of migrating during deposition and/or annealing and accumulates at grain boundaries or comprises such a material. Thus, the surface of the semiconductor layer 4, which is directly adjacent to the substrate 2, is planarized.

The growth substrate 1 according to the exemplary embodiment of FIG. 14 comprises a second intermediate layer 5′ compared to the growth substrate 1 of FIG. 13. The growth substrate 1 of FIG. 14 comprises a substrate 2, a layer sequence 3 and a cover layer 6. Thereby, the layer sequence 3 comprises exactly two semiconductor layers 4, 4′ and exactly two intermediate layers 5, 5′. The intermediate layer 5 is arranged between the substrate 2 and the semiconductor layer 4, the intermediate layer 5′ between the semiconductor layers 4, 4′. In other words, the layer sequence 3 is structured in such a way that the semiconductor layers 4, 4′ and the intermediate layers 5, 5′ are arranged alternately and that the intermediate layer 5 is directly adjacent to the substrate 2. The side of the layer sequence 3 facing away from the substrate 2 is covered with the cover layer 6.

The features and exemplary embodiments described in connection with the figures may be combined with one another in accordance with further exemplary embodiments, even if not all combinations are explicitly described. Furthermore, the exemplary embodiments described in combination with the figures may alternatively or additionally comprise further features as described in the general part.

The invention is not limited to the exemplary embodiments by the description thereof. Rather, the invention includes any new feature as well as any combination of features, which includes in particular any combination of features in the patent claims, even if this feature or combination itself is not explicitly stated in the patent claims or exemplary embodiments.

1.-15. (canceled)

16. A method for producing a growth substrate, the method comprising:
providing a substrate with a main surface;
arranging a layer sequence on the main surface of the substrate, wherein the layer sequence comprises at least one semiconductor layer comprising a III-V compound semiconductor material; and
annealing the layer sequence on the substrate,
wherein the layer sequence comprises at least one intermediate layer and/or wherein a cover layer is arranged on the layer sequence,
wherein a temperature during annealing is at least 1400° C.,
wherein the intermediate layer comprises a material selected from the following group: carbides, nitrides, oxides, oxynitrides, wherein the nitrides are nitrides of silicon, titanium, tantalum, yttrium, hafnium, scandium, tungsten, or zirconium, and
wherein the cover layer comprises one of the following materials: tungsten nitride, aluminum carbonitride, molybdenum, tungsten, titanium, tantalum, hafnium, aluminum, titanium tungsten, graphite, or a photoresist.

17. The method according to claim 16, wherein the III-V compound semiconductor material is a nitride compound semiconductor material.

18. The method according to claim 16, wherein the layer sequence comprises a plurality of semiconductor layers and a plurality of intermediate layers, and wherein the semiconductor layers and the intermediate layers are arranged alternately.

19. The method according to claim 16, wherein the semiconductor layer and/or the intermediate layer is applied by one of the following methods: MOVPE, sputtering, PECVD, or ALD.

20. The method according to claim 16, wherein the temperature during annealing is at least 1500° C.

21. The method according to claim 16, further comprising removing the cover layer after annealing.

22. A growth substrate comprising:
a substrate comprising a main surface; and
a layer sequence arranged on the main surface of the substrate,
wherein the layer sequence comprises at least one semiconductor layer comprising a III-V compound semiconductor material,
wherein the layer sequence comprises at least one intermediate layer and/or wherein a cover layer is arranged on the layer sequence,
wherein a material of the intermediate layer is stable at a temperature of greater than or equal to 1400° C.,
wherein the intermediate layer comprises a material selected from the following group: carbides, nitrides, oxides, oxynitrides, wherein the nitrides are nitrides of silicon, titanium, tantalum, yttrium, hafnium, scandium, tungsten, or zirconium, and
wherein the cover layer comprises one of the following materials: tungsten nitride, aluminum carbonitride, molybdenum, tungsten, titanium, tantalum, hafnium, aluminum, titanium tungsten, graphite, or a photoresist.

23. The growth substrate according to claim 22, wherein the layer sequence comprises at least one intermediate layer.

24. The growth substrate according to claim 22, wherein the layer sequence comprises a plurality of semiconductor layers and a plurality of intermediate layers, and wherein the semiconductor layers and the intermediate layers are arranged alternately.

25. The growth substrate according to claim 22, wherein one of the semiconductor layers is directly adjacent to the substrate.

26. The growth substrate according to claim 22, wherein one of the intermediate layers is directly adjacent to the substrate.

27. The growth substrate according to any of claim 22, wherein the semiconductor layer comprises a thickness of at most 600 nanometers.

28. The growth substrate according to any of claim 22, wherein the intermediate layer comprises between 1 and 100 monolayers, both inclusive.

29. The growth substrate according to claim 22, wherein the material of the intermediate layer is stable at the temperature of greater than or equal to 1600° C.
